(19) United States
(12) Patent Application Publication
(10) Pub. No.: US 2019/0387616 A1
(43) Pub. Date: Dec. 19, 2019

(54) LIGHT EMITTING ELEMENT

(71) Applicant: Chunghwa Picture Tubes, LTD., Taoyuan City (TW)

(72) Inventors: Wen-Jiunn Hsieh, New Taipei City (TW); Chao-Wen Yeh, Taoyuan City (TW)

(73) Assignee: Chunghwa Picture Tubes, LTD., Taoyuan City (TW)

(21) Appl. No.: 16/111,196

(22) Filed: Aug. 23, 2018

(30) Foreign Application Priority Data
Jun. 15, 2018 (CN) 201810621272.1

(51) Int. Cl. H05K 1/02; H01L 33/62; H01L 33/60; H01L 33/50; H05K 1/18

(52) U.S. Cl. CPC H05K 1/0274; H01L 33/62; H01L 33/60; H01L 33/507; H05K 1/181; H05K 2201/0218; H05K 2201/2081; H05K 2201/0215; H05K 2201/0209; H05K 2201/10106; H05K 2201/10674; H01L 33/502

(57) ABSTRACT

The present invention discloses a light emitting element comprising a printed circuit board and a light emitting diode. The printed circuit board comprises a photosensitive solder resist layer. Materials of the photosensitive solder resist layer comprise a reflective material and at least one of a conductive nanoparticle and a photoluminescent material. The light emitting diode is disposed on the photosensitive solder resist layer of the circuit board, and is electrically connected to the printed circuit board. By adding at least one of the conductive nanoparticle and the photoluminescent material, the light emitting element of the present invention reduces the photodegradation of the solder resist layer, and improves the reflectivity of the photosensitive solder resist layer.

### CROSS-REFERENCE TO RELATED APPLICATION

This application claims the priority benefit of China application serial no. 201810621272.1, filed on Jun. 15, 2018. The entirety of the above-mentioned patent application is hereby incorporated by reference herein and made a part of this specification.

### BACKGROUND OF THE INVENTION

### 1. Field of the Invention

The present invention relates to a light emitting element, and more particularly to a light emitting element that uses a reflective material and at least one of a conductive nanoparticle and a photoluminescent material as materials of a photosensitive solder resist layer.

### 2. Description of Related Art

Light emitting diodes (LEDs) have advantages such as long life, small size, high shock resistance, low heat generation, and low power consumption, and thus have been widely used as indicators or light sources in household and various devices. In recent years, light emitting diodes have been developed toward multiple colors and high brightness, so their application fields have been extended to large outdoor billboards, traffic signal lights and related fields. In the future, light emitting diodes may even become main illumination sources with functions of both power saving and environmental protection.

Generally, for a display device having a light emitting diode die, a light emitting diode is disposed on a circuit board, and an outermost layer of a commonly used circuit board is a green solder resist layer (commonly known as: green paint). In addition, a commonly used light emitting diode die mainly emits visible light within a wavelength range of 450 nanometers (nm) to 700 nm, but in an ultraviolet light region (e.g., less than 400 nm), the light emitting diode die may still emit some slight light. For example, when a single light emitting diode is driven by a low current, the ratio of the intensity of radiated ultraviolet light to blue light is at least about 0.1%, while the ratio of the intensity of ultraviolet light to blue light radiated by a blue light emitting diode is generally about 1.8%. Under long-term use, ultraviolet light will cause cracking of a green solder resist layer (commonly known as yellowing/brownish). Therefore, the reliability of the display device is also reduced accordingly.

### SUMMARY OF THE INVENTION

The present invention is directed to a light emitting element for improving the reflectivity, and by adding at least one of a conductive nanoparticle and a photoluminescent material, the problem of photodegradation of a reflective material is avoided, and the reflectivity of the reflective material is improved.

According to an embodiment of the present invention, a light emitting element comprises a printed circuit board and a light emitting diode. The printed circuit board comprises a photosensitive solder resist layer. Materials of the photosensitive solder resist layer comprise a reflective material and at least one of a conductive nanoparticle and a photoluminescent material. The light emitting diode is disposed on the photosensitive solder resist layer of the circuit board, and the light emitting diode is electrically connected to the printed circuit board.

In an embodiment of the present invention, the photosensitive solder resist layer is of a single-layer structure.

In an embodiment of the present invention, the photosensitive solder resist layer comprises a first layer and a second layer that are in contact with each other. The material of the first layer comprises the reflective material. The material of the second layer comprises at least one of the conductive nanoparticle and the photoluminescent material. The second layer is disposed between the first layer and the light emitting diode.

In an embodiment of the present invention, the printed circuit board further comprises a plurality of conductive terminals penetrating the photosensitive solder resist layer. The light emitting diode is disposed on the circuit board in a flip chip manner, and the light emitting diode is electrically connected to the printed circuit board through a plurality of conductive terminals.

In an embodiment of the present invention, the photoluminescent material releases light within a wavelength range of 450 nm to 700 nm if absorbing light having a wavelength of less than 400 nm.

In an embodiment of the present invention, the weight percentage concentration of the photoluminescent material in the photosensitive solder resist layer is from 5% to 50%.

In an embodiment of the present invention, the particle size of the conductive nanoparticle is from 0.5 nm to 100 nm.

In an embodiment of the present invention, the ratio of the weight of the conductive nanoparticle to the weight of the photoluminescent material is from 1% to 50%.

In an embodiment of the present invention, the photosensitive solder resist layer is white.

In an embodiment of the present invention, the reflective material comprises anatase titanium dioxide.

In an embodiment of the present invention, the conductive nanoparticle is one or more selected from the group consisting of gold, silver, platinum, copper, aluminum, silicon, and gallium arsenide.

In an embodiment of the present invention, the photoluminescent material is one or more selected from the group consisting of BaMgAl:Eu; BaMgAl:Eu, Mn; GdOS:Eu; Y₂O₃:Eu; and YVO₄:Nd.

In the light emitting device according to embodiments of the present invention, the light emitting diode of the present invention is disposed on the photosensitive solder resist layer of the printed circuit board, and the materials of the photosensitive solder resist layer comprise the reflective material and at least one of the conductive nanoparticle and the photoluminescent material. By adding the reflective material and at least one of the conductive nanoparticle and the photoluminescent material, the degradation of the solder resist layer can be reduced, the reflectivity of the reflective material can be improved, and the light utilization efficiency and reliability of the light emitting element can also be improved.

### BRIEF DESCRIPTION OF THE DRAWINGS

The accompanying drawings are included to provide a further understanding of the invention, and are incorporated in and constitute a part of this specification. The drawings illustrate embodiments of the present invention and, together with the description, serve to explain the principles of the invention.

FIG. 1 is a schematic sectional view of a light emitting element according to an embodiment of the present invention.

FIG. 2 is a schematic partial enlarged view of a printed circuit board of a first embodiment.

FIG. 3 is a schematic partial enlarged view of a printed circuit board of a second embodiment.

### DESCRIPTION OF THE EMBODIMENTS

Hereinafter, embodiments of the present invention will be illustrated in detail with reference to the accompanying drawings. However, the present invention may be implemented in many different forms and should not be construed as limited to the embodiments described herein. More particularly, these embodiments are disclosed so as to make the disclosure thorough and complete, and to fully convey the concept of the present invention to those skilled in the art, and the present invention will only be defined by the appended claims. Throughout the specification, the same reference numbers represent the same parts, and in order to make embodiments of the present invention clear, the size of some portions may be exaggerated.

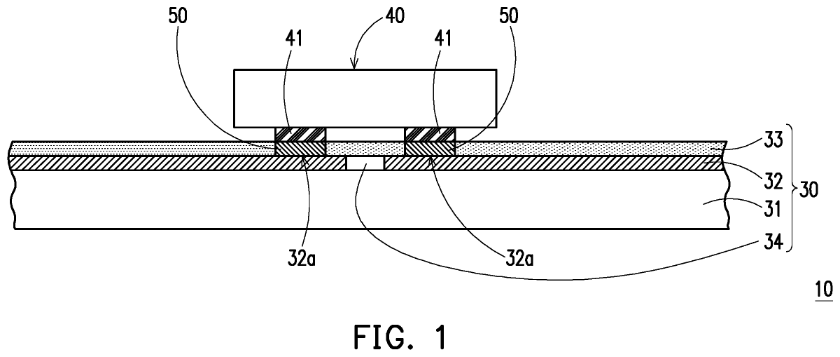

FIG. 1 is a schematic sectional view of a light emitting element according to an embodiment of the present invention.

Referring to FIG. 1, a light emitting device 10 comprises a printed circuit board 30 and a light emitting diode 40. The printed circuit board 30 comprises a substrate 31, a wiring layer 32, a photosensitive solder resist layer 33, and a dielectric layer 34. The wiring layer 32 and the dielectric layer 34 are disposed on the substrate 31. Different wires in the wiring layer 32 may be separated from each other by the dielectric layer 34. The photosensitive solder resist layer 33 covers the wiring layer 32, or further covers part of the dielectric layer 34. The photosensitive solder resist layer 33 comprises a plurality of openings to expose part of the wiring layer 32. Generally, a portion of the wiring layer 32 exposed by the photosensitive solder resist layer 33 may be referred to as contact pads 32a, such that the printed circuit board 30 may be electrically connected to other electronic components (e.g., the light emitting diode 40) through the contact pads 32a. In addition, if the substrate 31 is made of a hard material, the printed circuit board 30 may be a hard printed circuit board. In addition, if the substrate 31 is made of a soft material, the printed circuit board 30 may be a soft printed circuit board.

In this embodiment, the wiring layer 32 is of a single-layer structure, but the present invention is not limited thereto. In other embodiments, the wiring layer may be of a multi-layer structure, and the multi-layer wiring layer may comprise a dielectric layer between layers. Also, the multi-layer wiring layer may be electrically connected to each other through conductive vias. Of course, the dielectric layer 34 may also be of a single-layer structure or a multi-layer structure.

In this embodiment, the printed circuit board 30 may be electrically connected to other electronic components (e.g., the light emitting diodes 40) through conductive terminals 50 connected to the contact pads 32a, but the present invention is not limited thereto. The conductive terminals 50 are, for example, solder balls, but the present invention is not limited thereto. In other embodiments, the printed circuit board 30 may be electrically connected to other electronic components through bonding wires connected to the contact pads 32a. In addition, an insulated photosensitive solder resist layer 33 may also avoid unexpected contact between adjacent or close conductive terminals 50 from each other.

The light emitting diode 40 is disposed on the photosensitive solder resist layer 33 of the printed circuit board 30, and the light emitting diode 40 is electrically connected to the printed circuit board 30. In this embodiment, the light emitting diode 40 is disposed on the printed circuit board 30 in a flip chip manner, but the present invention is not limited thereto. The light emitting diode 40 electrically connects electrodes 41 of the light emitting diode 40 to the printed circuit board 30 through the conductive terminals 50.

In one embodiment, the photosensitive solder resist layer 33 may be white. Compared to a commonly used green solder resist layer, a white photosensitive solder resist layer 33 may reflect more visible light. Therefore, the white photosensitive solder resist layer 33 can have a better reflection effect and yellowing/brownish resistance, thereby improving the light utilization efficiency, reflectivity, and reliability of the light emitting element 10.

The composition and arrangement of the photosensitive solder resist layer of the printed circuit board may be, for example, described in the following embodiments. In addition, the drawings of the following embodiments are intended to more fully illustrate the present invention. However, the present invention can be embodied in various different forms and should not be limited to the embodiments described herein. The thicknesses of layers and regions in the drawings may be exaggerated for clarity. The same or similar reference numbers represent the same or similar parts, and the descriptions thereof are omitted in the following paragraphs.

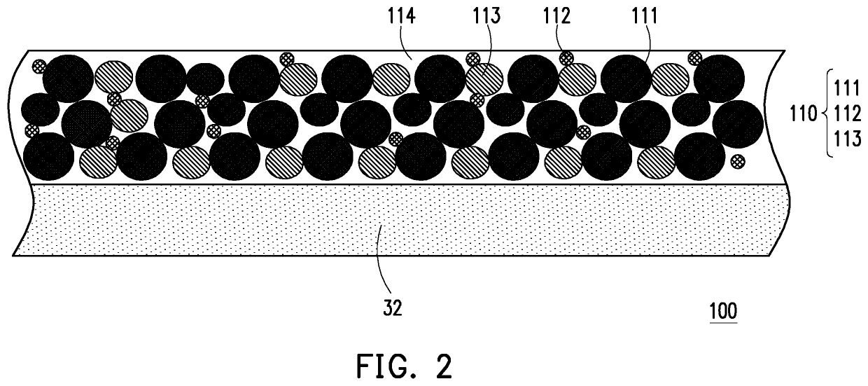

FIG. 2 is a schematic partial enlarged view of a printed circuit board of a first embodiment. Specifically, a printed circuit board 100 of this embodiment may be used as the printed circuit board 30 of the above embodiment. The arrangement of a photosensitive solder resist layer 110 in the printed circuit board 100 may be similar to that of the photosensitive solder resist layer 33 in the printed circuit board 30.

Referring to FIG. 2, materials of the photosensitive solder resist layer 110 comprise a reflective material 111 and at least one of a conductive nanoparticle 112 and a photoluminescent material 113. In this embodiment, the photosensitive solder resist layer 110 is of a single-layer structure, but the present invention is not limited thereto. In an embodiment, the photosensitive solder resist layer 110 having a single-layer structure is, for example, composed of the reflective material 111 doped with the conductive nanoparticle 112 and the photoluminescent material 113. The reflective material 111, the conductive nanoparticle 112, and the photoluminescent material 113 are fixed on a wiring layer 32 through an adhesive 114. The adhesive 114 is, for example, resin, and may insulate the photosensitive solder resist layer 110.

The reflective material 111 may be used for reflecting part of light emitted from the light emitting diode 40 (as shown in FIG. 1) to the printed circuit board 100, so as to improve the light utilization efficiency and the reflectivity of the light emitting element 10 (as shown in FIG. 1). The material of the photosensitive solder resist layer 110 of the present invention comprises at least one of the conductive nanoparticle 112 and the photoluminescent material 113. Therefore, the reflective material 111 may use anatase titanium dioxide. Anatase titanium dioxide has a higher reflectivity than rutile titanium dioxide. Therefore, by using anatase titanium dioxide and at least one of the conductive nanoparticle 112 and the photoluminescent material 113, the photocatalytic effect due to ultraviolet light emitted from the light emitting diode 40 can be reduced, thereby reducing the degradation of the reflective material 111. In addition, the reflectivity of the photosensitive solder resist layer 110 may be increased so as to improve the light utilization efficiency and reliability of the light emitting element 10.

The photoluminescent material 113 is preferably a white photoluminescent material 113. The reason is that when the photoluminescent material 113 is irradiated with white light, the color reflected by the photoluminescent material 113 is white. Therefore, decrease of reflectivity caused by the decrease in whiteness of the photosensitive solder resist layer 110 due to the addition of the photoluminescent material 113 may be reduced. In addition, if the photoluminescent material 113 absorbs ultraviolet light (e.g., light having a wavelength of less than 400 nm), the photoluminescent material 113 may emit visible red, green, or blue light (e.g., light within a wavelength range of 450 nm to 700 nm). Therefore, the photocatalytic effect of the titanium dioxide can be reduced through the photoluminescent material 113, so as to improve the light utilization efficiency and reliability of the light emitting element 10. The photoluminescent material 113 is, for example, one or more selected from the group consisting of BaMgAl:Eu; BaMgAl:Eu, Mn; GdOS:Eu; Y₂O₃:Eu; YVO₄:Nd; or other suitable phosphorescent pigments. For example, taking a BaMgAl:Eu-based phosphorescent pigment as the photoluminescent material 113 as an example, the photoluminescent effect of the photoluminescent material 113 can absorb ultraviolet emitted from the light emitting diode 40 and convert the same into visible light that does not cause the photocatalytic effect of titanium dioxide.

The concentration of the photoluminescent material 113 is between 5% and 50% by weight percentage concentration of solid components in the photosensitive solder resist layer 110. If the above concentration is less than 5%, the light conversion effect is not significant, and some titanium dioxide may still generate the photocatalytic effect. If the above concentration is greater than 50%, the reflection of titanium dioxide may be affected. In an embodiment of the present invention, the concentration of the photoluminescent material 113 is between 5% and 20% by weight percentage concentration of the solid components in the photosensitive solder resist layer 110, so that the photosensitive solder resist layer 110 may have a better light conversion and reflection effect with a lower material cost.

The conductive nanoparticle 112 is one or more selected from the group consisting of gold, silver, platinum, copper, aluminum, silicon, gallium arsenide, and other metal materials, semiconductor materials or alloys. Generally, any material that has a negative real part permittivity value and a small imaginary part permittivity value may be the suitable material of the conductive nanoparticle 112. In the nanoscale, the physical or chemical properties exhibited by the conductive nanoparticle 112 may be different from a bulk of the same material. For example, the surface plasma effect produced by the conductive nanoparticle 112 (e.g., localized surface plasmon resonance (LSPR) effect of the nano-sized conductor structure) can improve the light conversion efficiency of the photoluminescent material 113. Therefore, if the conductive nanoparticle 112 is added, the usage amount of the photoluminescent material 113 may be reduced accordingly, thereby reducing the material cost. The particle size of the conductive nanoparticle 112 is from 0.5 nm to 100 nm. The ratio of the weight of the conductive nanoparticle 112 to the weight of the photoluminescent material 113 is from 1% to 50%.

In addition, if the material of the conductive nanoparticle 112 is a metal, the metal fluorescence effect of the metal conductive nanoparticle may also absorb the ultraviolet light emitted from the light emitting diode 40 and convert the same into visible light that will not cause the photocatalytic effect of the titanium dioxide.

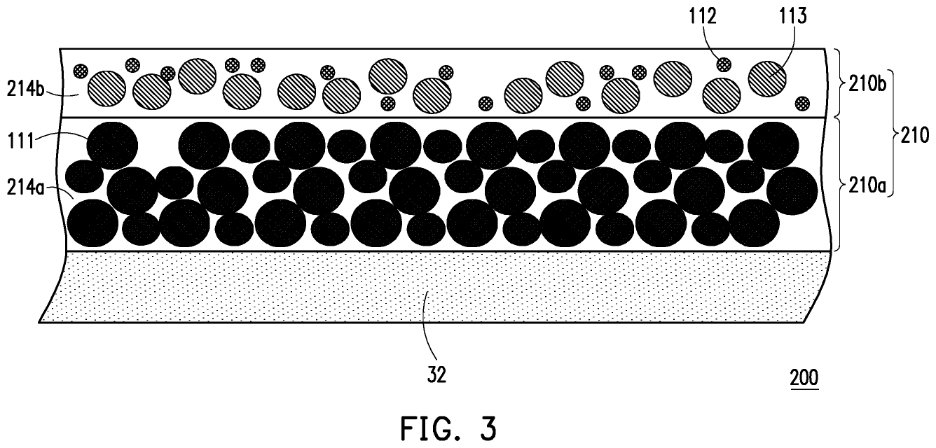

FIG. 3 is a schematic partial enlarged view of a printed circuit board of a second embodiment. Specifically, a printed circuit board 200 of this embodiment may be used as the printed circuit board 30 of the above embodiment. The arrangement of a photosensitive solder resist layer 210 in the printed circuit board 200 may be similar to that of the photosensitive solder resist layer 33 in the printed circuit board 30.

Referring to FIG. 3, materials of the photosensitive solder resist layer 210 comprise a reflective material 111 and at least one of a conductive nanoparticle 112 and a photoluminescent material 113. In this embodiment, the photosensitive solder resist layer 210 is of a two-layer structure. As shown in FIG. 3, the photosensitive solder resist layer 210 comprises a first layer 210a and a second layer 210b that are in contact with each other.

The material of the first layer 210a comprises the reflective material 111, and the reflective material 111 is fixed by an adhesive 214a.

The material of the second layer 210b comprises at least one of the conductive nanoparticle 112 and the photoluminescent material 113. The conductive nanoparticle 112 and/or the photoluminescent material 113 are fixed by an adhesive 214b. The second layer 210b is disposed between the first layer 210a and the light emitting diode 40 (as shown in FIG. 1). In this embodiment, the material of the adhesive 214a and the material of the adhesive 214b may be similar to the material of the adhesive 114. In addition, the material of the adhesive 214a and the material of the adhesive 214b may be the same or different from each other, and the present invention is not limited thereto.

Based on the above disclosure, the light emitting diode of the present invention is disposed on the photosensitive solder resist layer of the printed circuit board, and the materials of the photosensitive solder resist layer comprise the reflective material and at least one of the conductive nanoparticle and the photoluminescent material. By adding the reflective material and at least one of the conductive nanoparticle and the photoluminescent material, the degradation of the solder resist layer can be reduced, the reflectivity of the reflective material can be improved, and the light utilization efficiency and reliability of the light emitting element can also be improved.

Finally, it should be stated that: the above embodiments are only to illustrate the technical solutions of the present invention, rather than limit thereto; although the present invention has been illustrated in detail with reference to the above embodiments, those of ordinary skill in the art should understand that: they may still modify the technical solutions described in the above embodiments or equivalently replace some or all of the technical features; and these modifications or replacements do not deviate the essence of corresponding technical solutions from the scope of the technical solutions in the embodiments of the present invention.

What is claimed is:

1. A light emitting element comprising:
a printed circuit board, comprising a photosensitive solder resist layer, wherein materials of the photosensitive solder resist layer comprise:
a reflective material; and
at least one of a conductive nanoparticle and a photoluminescent material; and
a light emitting diode disposed on the photosensitive solder resist layer of the circuit board, and electrically connected to the printed circuit board.

2. The light emitting element according to claim 1, wherein the photosensitive solder resist layer is of a single-layer structure.

3. The light emitting element according to claim 1, wherein the photosensitive solder resist layer comprises a first layer and a second layer that are in contact with each other, the material of the first layer comprises the reflective material, the material of the second layer comprises at least one of the conductive nanoparticle and the photoluminescent material, and the second layer is disposed between the first layer and the light emitting diode.

4. The light emitting element according to claim 1, wherein the printed circuit board further comprises a plurality of conductive terminals penetrating the photosensitive solder resist layer, the light emitting diode is disposed on the circuit board in a flip chip manner, and the light emitting diode is electrically connected to the printed circuit board through the plurality of conductive terminals.

5. The light emitting element according to claim 1, wherein the photoluminescent material releases light within a wavelength range of 450 nm to 700 nm if absorbing light having a wavelength of less than 400 nm.

6. The light emitting element according to claim 1, wherein the weight percentage concentration of the photoluminescent material in the photosensitive solder resist layer is from 5% to 50%.

7. The light emitting element according to claim 6, wherein the weight percentage concentration of the photoluminescent material in the photosensitive solder resist layer is from 5% to 20%.

8. The light emitting element according to claim 1, wherein the particle size of the conductive nanoparticle is from 0.5 nm to 100 nm.

9. The light emitting element according to claim 1, wherein the photosensitive solder resist layer is white.

10. The light emitting element according to claim 1, wherein the reflective material comprises titanium dioxide.

11. The light emitting element according to claim 10, wherein the titanium dioxide is anatase titanium dioxide.

12. The light emitting element according to claim 1, wherein the material of the photosensitive solder resist layer comprises the conductive nanoparticle, and the conductive nanoparticle is one or more selected from the group consisting of metal, silicon, and gallium arsenide.

13. The light emitting element according to claim 12, wherein the material of the conductive nanoparticle is one or more selected from the group consisting of gold, silver, platinum, copper, and aluminum.

14. The light emitting element according to claim 1, wherein the material of the photosensitive solder resist layer comprises the photoluminescent material, and the photoluminescent material comprises a phosphorescent pigment.

15. The light emitting element according to claim 14, wherein the phosphorescent pigment is one or more selected from the group consisting of BaMgAl:Eu; BaMgAl:Eu, Mn; GdOS:Eu; Y₂O₃:Eu; and YVO₄:Nd.

16. The light emitting element according to claim 1, wherein the material of the photosensitive solder resist layer comprises the conductive nanoparticle, the photoluminescent material, and the reflective material.

17. The light emitting element according to claim 16, wherein the ratio of the weight of the conductive nanoparticle to the weight of the photoluminescent material is from 1% to 50%.
